(19) United States
(12) Patent Application Publication
(10) Pub. No.: US 2026/0030419 A1
(43) Pub. Date: Jan. 29, 2026

(54) LOOKAHEAD MONITORING IN A DRILLING ENVIRONMENT FOR A PROJECTED TRAJECTORY PATH

(71) Applicant: Schlumberger Technology Corporation, Sugar Land, TX (US)

(72) Inventors: Kewen Sun, Beijing (CN); Chao Mu, Houston, TX (US); Lu Jiang, Beijing (CN); Tao Yu, Beijing (CN); Graeme Paterson, Beijing (CN)

(21) Appl. No.: 18/780,528

(22) Filed: Jul. 23, 2024

(51) Int. Cl. G06F 30/28; E21B 7/04; E21B 47/09

(52) U.S. Cl. CPC G06F 30/28; E21B 7/04; E21B 47/09; E21B 2200/20

(57) ABSTRACT

This disclosure relates to a predictive lookahead system that generates simulated or predicted wellbore trajectory plans in a drilling environment and determines when a simulated wellbore trajectory plan is at risk based on various lookahead metrics, such as torque and drag (T&D) metrics and hydraulic pressure metrics. For instance, the predictive lookahead system uses a predictive framework with various steps to determine if drilling metrics for a predictive wellbore trajectory plan, such as T&D metrics and/or hydraulic pressure metrics corresponding to subsurface formations, may exceed one or more risk threshold limits and cause damage to the drill bit, drill string, casing, and/or surface rig. The predictive lookahead system determines whether a predictive wellbore trajectory, which aims to converge with a previously planned wellbore trajectory, can proceed safely along the projected trajectory without exceeding T&D, pressure window, or other lookahead metric limits in the wellbore.

### BACKGROUND

Wellbores may be drilled into a surface location or seabed for various exploratory or extraction purposes. For example, a wellbore may be drilled to access fluids, such as liquid and gaseous hydrocarbons, stored in subterranean formations and to extract the fluids from the formations. Wellbores used to produce or extract fluids may be formed in earthen formations using earth-boring tools such as drill bits for drilling wellbores and reamers for enlarging the diameters of wellbores. In determining where to drill, downhole drilling systems utilize field planning to explore and identify environmental assets. Downhole drilling systems then generate a wellbore drilling plan to optimally leverage identified environment assets.

More recently, wellbore drilling plans include a planned route that requires directional drilling. Directional drilling allows assets not directly below the surface location of a rig to be accessed by drilling portions of wellbores in a non-vertical direction. When following a wellbore drilling plan using non-directional drilling (e.g., drilling straight down), drilling conditions can cause the wellbore to deviate off course. The complexities added with directional drilling can create further deviations from a wellbore drilling plan.

An example of these complexities is torque and drag (T&D), which can result in stuck pipes or drill strings. To elaborate, with directional drilling, the drill string does not hang straight down but winds around curves and turns. In these cases, the drill strings experience various forces and other dynamics as they contact the wellbore casing at one or more locations downhole. To determine these forces, some downhole drilling systems perform a torque and drag analysis on the drill string. For example, the torque and drag analysis includes determining tension within the drill string, torque on the drill string, and frictional forces resisting rotational and axial motion of the drill string, among others. In particular, drill string contact with wellbore casing can cause friction forces, which hinder the axial movement of the drill string (drag force) and its rotation (torque).

Another example of the above complexities is hydraulic pressure. When hydraulic pressure is too low, an unexpected influx (or kick) of formation fluids (e.g., oil, gas, or water) can flow into the wellbore during the drilling process. When hydraulic pressure is too high, fractures and losses can occur in the formation of surrounding rock breaks, which may allow an influx of fluids, such as drilling mud, to flow into fractures or fissures. Both scenarios pose significant risks to drilling operations.

While current downhole drilling systems provide valuable insights into the drilling parameters of a drill string to assist in safely drilling within acceptable parameters, current downhole drilling systems still face challenges with drilling operations and overall drilling efficiency.

### BRIEF DESCRIPTION OF THE DRAWINGS

The following detailed description provides specific and detailed implementations accompanied by drawings. Additionally, each of the figures listed below corresponds to one or more implementations discussed in this disclosure.

FIG. 1 is a representation of a drilling system for drilling an earth formation to create a wellbore.

FIG. 2 illustrates an example environment of a subsurface structure system where a predictive lookahead system is implemented.

FIG. 3A illustrates an example of simulating a predicted trajectory path for a wellbore that has deviated from a wellbore drilling plan.

FIG. 3B illustrates an example of simulating multiple predicted trajectory paths for the wellbore.

FIG. 4 illustrates an example of simulating multiple iterations of a predicted trajectory path.

FIG. 5 illustrates determining torque and drag (T&D) metrics based on a predicted trajectory path.

FIG. 6 illustrates monitoring T&D limits for a predicted trajectory path.

FIG. 7 illustrates monitoring pressure window limits for hydraulic pressure in a predicted trajectory path.

FIG. 8 illustrates a series of acts of computer-implemented methods for determining whether drilling metrics are within threshold limits for a predicted wellbore trajectory path in a drilling environment.

FIG. 9 illustrates a series of acts of computer-implemented methods for determining whether T&D metrics are within threshold T&D limits for a predicted wellbore trajectory path in a drilling environment.

FIG. 10 illustrates a series of acts of computer-implemented methods for determining whether hydraulic pressure metrics are within pressure window threshold limits for a predicted wellbore trajectory path in a drilling environment.

FIG. 11 illustrates example components included within a computer system used to implement the predictive lookahead system.

### DETAILED DESCRIPTION

This disclosure relates to a predictive lookahead system that generates simulated or predicted wellbore trajectory plans in a drilling environment and determines when a simulated wellbore trajectory plan is at risk based on various lookahead metrics, such as torque and drag (T&D) metrics and hydraulic pressure metrics. For instance, the predictive lookahead system uses a predictive framework with various steps to determine if drilling metrics for a predictive wellbore trajectory plan, such as T&D metrics and/or hydraulic pressure metrics corresponding to subsurface formations, may exceed one or more risk threshold limits and cause damage to the drill bit, drill string, casing, and/or surface rig. The predictive lookahead system determines whether a predictive wellbore trajectory, which aims to converge with a previously planned wellbore trajectory, can proceed safely along the projected trajectory without exceeding T&D, pressure window, or other lookahead metric limits in the wellbore.

More specifically, this disclosure relates to devices, systems, and methods for monitoring real-time limit risks associated with drilling parameters of one or more predictive wellbore trajectory paths that seek to return a deviated wellbore to align with the original well plan previously planned. In this disclosure, these devices, systems, and methods are described in the context of a predictive lookahead system, which may automatically project, calculate, monitor, and report risk tolerance issues for one or more projected wellbore paths to ensure safely and effectively directing a wellbore back on track with its originally intended path.

To illustrate, in response to determining that a current drilling location has deviated from a wellbore drilling plan, the predictive lookahead system simulates a predicted trajectory path from the current wellbore location back to the wellbore drilling plan at or before a target endpoint. In addition, the predictive lookahead system generates predicted drilling tolerance values (e.g., torque and drag or hydraulic pressure) for an estimated drill string residing in the first predicted trajectory path. Based on determining that the predicted drilling tolerance values for the estimated drill string exceed a threshold risk (e.g. a threshold torque and drag risk limit or a threshold pressure window risk limit), the predictive lookahead system provides a risk report that indicates a drilling tolerance risk (e.g., a torque or drag risk or a pressure window risk) associated with the first predicted trajectory path.

By way of context, wellbore drilling plans include a planned drilling path trajectory for drilling to a target location. Wellbore drilling plans may be thousands of feet long for drilling deep into the earth. Due to their length and uncertain conditions deep within the earth, estimating the exact trajectory in a wellbore drilling plan is difficult. For example, variations in geological features and formations often cause deviations from the wellbore drilling plan. Often, wellbore drilling plans include control points at regular intervals to ensure that a wellbore is adhering to the wellbore drilling plan.

When deviations occur, a drilling assembly commonly tries to converge back to the original wellbore drilling plan. For example, many downhole drilling systems will attempt to converge with the wellbore drilling plan at the next control point on the wellbore drilling plan, if not prohibited by drilling capability constraints. However, as further described below, mapping and following a new course to the next control point often result in inefficiencies and may result in problematic issues that damage drilling equipment.

Accordingly, this application describes systems and methods for using a predictive lookahead system to determine ideal trajectories and ensure that a selected trajectory satisfies the operational conditions of the drilling equipment. In various instances, the predictive lookahead system utilizes one or more lookahead simulations (e.g., a T&D analysis and/or a hydraulic simulation) to detect the risks associated with a simulated trajectory. For example, using the predictive lookahead system, the trajectory that better reduces operational risk may be selected between two or more predicted trajectories. In addition, when risks are identified, the predictive lookahead system may take one or more actions so that the risks may be reduced.

As described in this disclosure, the predictive lookahead system delivers several significant technical benefits compared to existing downhole drilling systems. Moreover, the predictive lookahead system provides several practical applications that address problems related to downhole drilling and downhole drilling environments.

To illustrate, the predictive lookahead system provides improved efficiency and accuracy over existing downhole drilling systems by simulating one or more new drilling trajectories when a wellbore deviates from a drilling plan to converge. Unlike existing downhole drilling systems, the new drilling trajectory need not converge at the next control point of a wellbore drilling plan. Rather, the predictive lookahead system converges with the wellbore drilling plan at or before a target endpoint of a section of the plan. This allows the threat detection system to more accurately and efficiently generate predicted trajectories, reducing computational steps and excess processing that occurs by forcing convergence at the next control point regardless of the environmental conditions and whether such convergence is possible as this results in repeating several computational steps each time the new path does not converge at the next control point due to challenging drilling environment conditions. Instead, the predictive lookahead system allows wayward drilling equipment to return to the wellbore drilling plan at an optimal trajectory.

Additionally, the predictive lookahead system includes a practical application of returning a wellbore to a wellbore drilling plan without damaging to breaking drilling equipment. For example, by ensuring that the torque and drag and/or hydraulic pressure for a projected path are within operational limits and constraints, the predictive lookahead system ensures that a wellbore will safely converge with the wellbore drilling plan without damage due to a poorly or forced new trajectory.

Furthermore, in various instances, the predictive lookahead system allows for multiple predicted trajectories to be simulated and each tested for T&D and/or hydraulic pressure metrics. In these instances, the predictive lookahead system selects the trajectory with the most favorable metrics, ensuring the highest success of converging with the wellbore drilling plan with the least amount of stress to the drilling equipment and casing.

Turning now to the figures, additional details are provided regarding the components and features of the predictive lookahead system. Additional example implementations and details of the predictive lookahead system are discussed in connection with the accompanying figures.

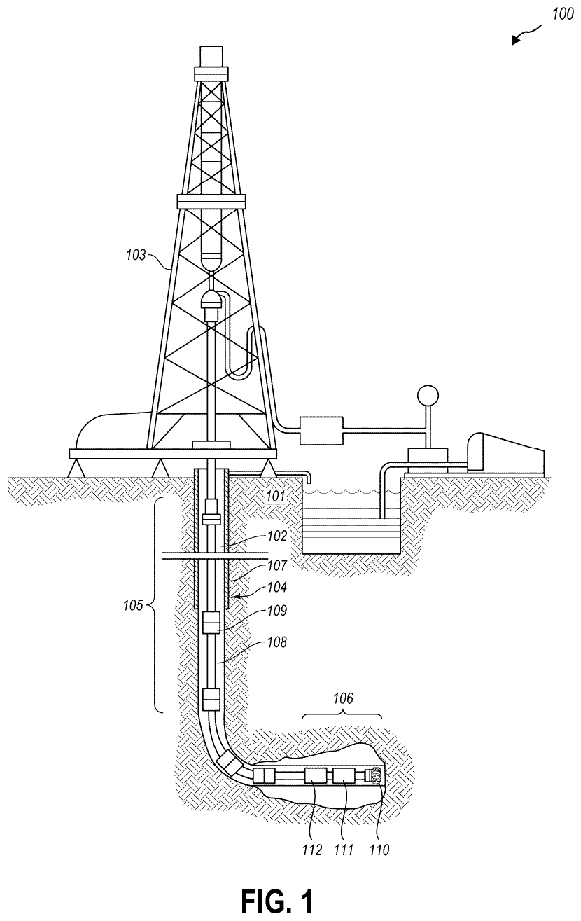

FIG. 1 shows an example representation of a drilling system for drilling an earth formation to create a wellbore according to some implementations. In particular, FIG. 1 provides additional context regarding a drilling system to which the predictive lookahead system often belongs. To illustrate, FIG. 1 shows an example of a drilling system 100 for drilling an earth formation 101 to form a wellbore 102. The drilling system 100 (e.g., a downhole drilling system) includes a drill rig 103 used to turn a drilling tool assembly 104 that extends downward into the wellbore 102. The drilling tool assembly 104 may include a drill string 105, a bottomhole assembly (“BHA 106”), and a bit 110 attached to the downhole end of the drill string 105.

The drill string 105 may include several joints of drill pipe 108 connected end-to-end through tool joints 109. The drill string 105 transmits drilling fluid through a central bore and transmits rotational power from the drill rig 103 to the BHA 106. In some embodiments, the drill string 105 may further include additional components such as subs, pup joints, etc. The drill pipe 108 provides a hydraulic passage through which drilling fluid is pumped from the surface. The drilling fluid discharges through nozzles, jets, or other openings in the bit 110 for purposes such as cooling the bit 110 and its cutting structures, lifting cuttings out of the wellbore 102 during drilling, controlling fluid influx in the well, maintaining wellbore integrity, and other functions.

The BHA 106 may include the bit 110 or other components. An example BHA 106 may include additional or different components (e.g., coupled between the drill string 105 and the bit 110). Examples of additional BHA components include drill collars, stabilizers, measurement-while-drilling (MWD) tools, logging-while-drilling (LWD) tools, downhole motors, underreamers, section mills, hydraulic disconnects, jars, vibration or damping tools, other components, or combinations of these components.

The BHA 106 may further include a directional tool 111 such as a bent housing motor or a rotary steerable system (RSS). The directional tool 111 may include directional drilling equipment that changes the direction of the bit 110, thereby altering the trajectory of the wellbore 102. In some cases, at least a portion of the directional tool 111 may maintain a geostationary position relative to an absolute reference frame, such as gravity, magnetic north, or true north. Using measurements obtained from this geostationary position, the directional tool 111 may locate the bit 110, modify its course, and guide the directional tool 111 along a projected trajectory. For instance, the BHA 106 (including the directional tool 111) is shown transitioning from vertical to horizontal drilling, causing the bit 110 to move along a horizontal path away from the drill rig 103.

In general, the drilling system 100 may include additional or different drilling components and accessories including special valves (e.g., blowout preventers and safety valves). Additional components within the drilling system 100 may be categorized as part of the drilling tool assembly 104, the drill string 105, or part of the BHA 106 depending on their specific locations within the drilling system 100.

The bit 110 in the BHA 106 may be any type of bit suitable for degrading downhole materials such as the earth formation 101. Examples of drill bits used for drilling earth formations include fixed-cutter or drag bits, roller cone bits, and combinations thereof. In other embodiments, the bit 110 may be a mill used for removing metal, composite, elastomer, or other downhole materials, or combinations thereof. For instance, the bit 110 may be used with a whipstock to mill into the casing 107 lining the wellbore 102. The bit 110 may also be a junk mill used to mill away tools, plugs, cement, or other materials within the wellbore 102, or combinations thereof. Swarf or other cuttings formed by the use of a mill may be lifted to the surface or allowed to fall downhole. In still other embodiments, the bit 110 may include a reamer. For instance, an underreamer may be used in connection with a drill bit, and the drill bit may bore into the formation while the underreamer enlarges the size of the bore.

While performing downhole activities, a subsurface structure system may receive information regarding the earth formation 101 based on one or more sets of survey data. For example, the BHA 106 may include downhole tool sensors 112 (e.g., an LWD tool). The downhole tool sensors 112 may collect downhole measurement data about the earth formation 101 including formation pressures and properties. The downhole measurement data may be collected by transmitting to the surface and may be assembled in a wellbore data log. In some instances, this information includes a current wellbore location, such as the location of the bit 110 and/or the BHA 106.

In various implementations, the wellbore 102 follows a wellbore drilling plan. As mentioned, a wellbore drilling plan maps out a projected trajectory for the wellbore 102 to follow. The wellbore drilling plan may include various control points for checking the current location of the BHA 106 and/or bit 110 in comparison to the wellbore drilling plan. In addition, a wellbore drilling plan may include sections and/or target endpoints.

As mentioned above, when drilling according to a wellbore drilling plan, a wellbore may deviate from the plan. For example, a wellbore exhibits unwanted curvature, which increases tortuosity (e.g., the measure of deviation from a straight line) from the wellbore drilling plan, due to the drilling environment. The results of these deviations can include non-straight and/or non-smoothly curving wellbore paths.

Deviations in a wellbore can cause problems for a bit and a drill string. For example, a drill string may become stuck, jammed, or restricted when a curve is too sharp or when multiple curves in different directions (e.g., opposite directions) combine to jam up a drill string, preventing it from raising, dropping, and/or turning. Contact between a drill string and a wellbore may result in frictional resistance to movement, both rotational and axial, leading to various stresses, forces, twisting, bending, compression, and tension among other dynamics experienced by drill strings.

As described in this disclosure, the predictive lookahead system provides a framework to eliminate, minimize, and/or reduce risks caused by wellbore deviation. For instance, in various implementations, the predictive lookahead system determines and assesses the dynamics acting on an estimated drill string to ensure that one or more working or failure limits are not met or exceeded for one or more components of the drill string if a predicted trajectory is selected. In this way, the predictive lookahead system prevents the drill string from becoming stuck, jammed, or restricted at one or more locations in the wellbore.

As described in this disclosure, the predictive lookahead system provides a framework to eliminate, minimize, and/or reduce risks caused by wellbore deviation. For instance, in various implementations, the predictive lookahead system determines and assesses the dynamics acting on an estimated drill string to ensure that one or more working or failure limits are not met or exceeded for one or more components of the drill string if a predicted trajectory is selected. In this way, the predictive lookahead system prevents the drill string from becoming stuck, jammed, or restricted at one or more locations in the wellbore.

As mentioned earlier, torque and drag (T&D) refer to determining, characterizing, measuring, and/or calculating the dynamics (e.g., forces, friction, torques, etc.) acting on a drill string (e.g., current or estimated). The process of determining T&D metrics is referred to as T&D analysis and typically involves determining axial and/or rotational forces acting on a drill string 105.

Additionally, hydraulic pressure refers to downhole fluid pressures corresponding to the drill string, annuluses, and casings. Often, hydraulic pressure corresponds to drilling mud and can change based on adjusting mud weight parameters. Hydraulic pressure is often determined using modeling and simulation based on fluid properties, trajectories, temperatures, geometries, and other hydraulic-related parameters.

In various implementations, the drilling system 100 is associated with one or more client devices that include a lookahead system. As described below, the lookahead system may facilitate calculating and/or assessing forces and/or other parameters that may act on the drill string in association with the drill string advancing into or being retrieved from the wellbore 102.

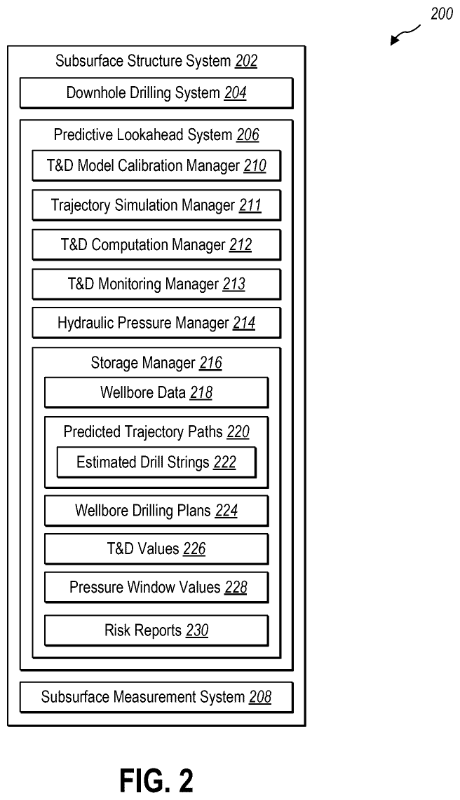

With the framework of the drilling system and an example operating environment described, this disclosure will now focus on describing implementations of the predictive lookahead system. For example, FIG. 2 provides additional details regarding implementing the threat detection system. To illustrate, FIG. 2 shows an environment 200 of a subsurface structure system 202 in which a predictive lookahead system 206 (e.g., a predictive torque and drag system or a predictive hydraulic pressure system) is implemented according to some embodiments.

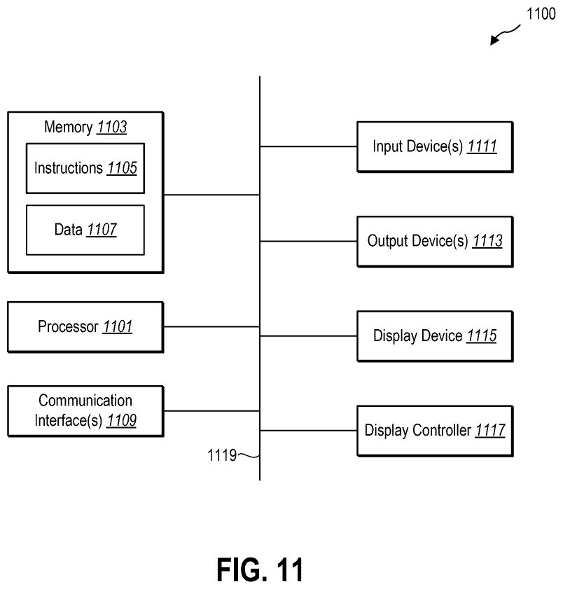

As illustrated, the subsurface structure system 202 includes various systems and components. For instance, the subsurface structure system 202 includes a downhole drilling system 204, the predictive lookahead system 206, and a subsurface measurement system 208. Each of these systems may be implemented on one or more computing devices. The subsurface structure system 202 may include additional devices and components not shown. Additionally, while FIG. 2 shows example arrangements and configurations of the subsurface structure system 202 and/or the predictive lookahead system 206, other arrangements and configurations are possible. Further, details regarding computing devices are provided below in connection with FIG. 11.

In various implementations, the downhole drilling system 204 controls the direction and trajectory of a drill and/or wellbore as it progresses through the subsurface formations. In various instances, a downhole drilling system 204 uses data analysis with drilling control to navigate through subsurface formations, maximize reservoir contact, minimize drilling risks, and optimize the placement of wellbores in the reservoirs. The downhole drilling system 204 operates in connection with the predictive lookahead system 206, for example, to select, steer, or direct the trajectory based on downhole features, and drilling calculations made for one or more trajectories.

In some implementations, the subsurface measurement system 208 uses one or more tools to collect and analyze geological features from below the Earth's surface. The subsurface measurement system 208 may use various downhole and/or surface instruments and methods to measure and monitor conditions, properties, and processes in subsurface environments, such as underground reservoirs, geological formations, and aquifers. The subsurface measurement system 208 may measure various subsurface properties at various positions, such as fluid properties, trajectories, temperatures, and geometries. In various implementations, a subsurface measurement system 208 includes sensors, probes, well-logging equipment, and remote sensing technologies to provide subsurface information. In various instances, the subsurface measurement system 208 provides a current location of a BHA and/or bit within a wellbore. In some instances, the subsurface measurement system 208 provides data that is used to determine a current location within a wellbore.

As shown, the subsurface structure system 202 includes the predictive lookahead system 206, which may communicate with the downhole drilling system 204 and the subsurface measurement system 208. The predictive lookahead system 206 may be located as part of a downhole assembly, located at the surface, or located at various locations. For example, in some instances, the predictive lookahead system 206 is implemented at the surface. In some implementations, the predictive lookahead system 206 is located near a downhole tool sensor, the bit, or the BHA.

The predictive lookahead system 206 includes various components to implement the functions, features, systems, and methods described in this document. To illustrate, the predictive lookahead system 206 includes a T&D model calibration manager 210, a trajectory simulation manager 211, a T&D computation manager 212, a T&D monitoring manager 213, a hydraulic pressure manager 214, and a storage manager 216. The storage manager 216 includes wellbore data 218, predicted trajectory paths 220 with estimated drill strings 222, wellbore drilling plans 224, T&D values 226, pressure window values 228, and risk reports 230.

As mentioned, the predictive lookahead system 206 includes a T&D model calibration manager 210. In various implementations, the T&D model calibration manager 210 calibrates a model that determines the torque and drag metrics of a drill string in a borehole (or an estimated drill string). In one or more embodiments, the T&D model calibration manager 210 applies a stiff-string model that uses a finite element method to model friction in directional wellbores. For instance, uncertain variables in the model input may be calibrated with data acquired during rig operations. For example, a free-rotation hook load may be used to calibrate the linear weight coefficient, a pick-up hook load may be used to calibrate a pick-up friction factor, and/or a slack-off hook load may be used to calibrate a slack-off friction factor.

In addition, the predictive lookahead system 206 includes the trajectory simulation manager 211. In various implementations, the trajectory simulation manager 211 determines one or more of the predicted trajectory paths 220 that include estimated drill strings 222. In various implementations, the trajectory simulation manager 211 utilizes the wellbore data 218 to determine the current location of the drill and determine if it is a threshold distance (e.g., a drilling plan distance deviation threshold) from a wellbore drilling plan. If so, the trajectory simulation manager 211 generates one or more simulated or predicted trajectory paths having one or more predicted or estimated drill strings. In various implementations, an estimated drill string includes some or all of the current drill string plus a predicted drill string within a projected or simulated trajectory path.

The trajectory simulation manager 211 may simulate one or more trajectories from the current location (e.g. current survey location or current hole bottom location) to a target endpoint of a wellbore drilling plan. In various implementations, the trajectory simulation manager 211 may use wellbore data 218, such as the current location of a bit in the wellbore, geological properties of the earth formation, information about the drilling tools (e.g., bottom-hole assemblies, casing sizes, etc.), and other information (e.g., risk tolerances, fluid weights and/or plans, bottom-hole pressures, drilling time, etc.) to simulate one or more predicted trajectory paths.

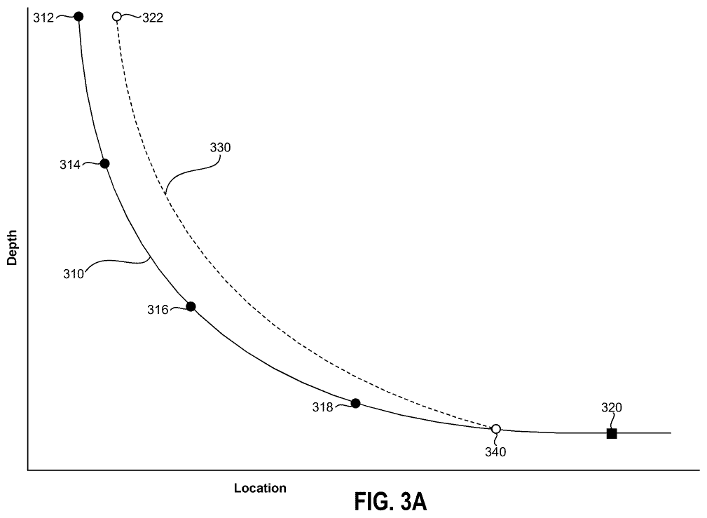

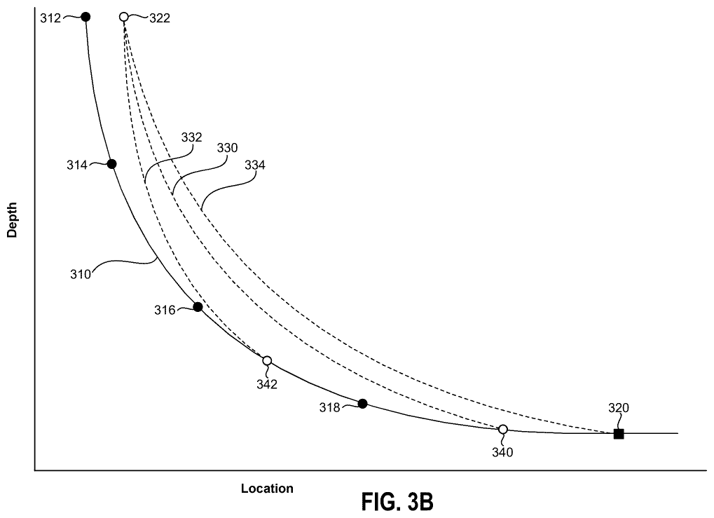

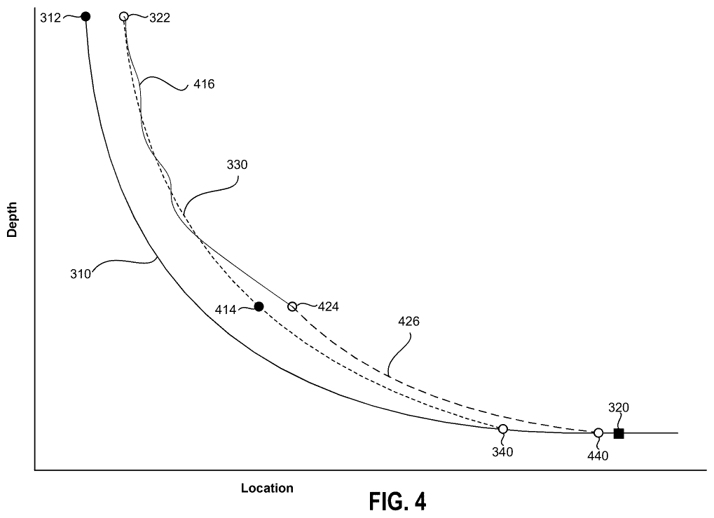

In some implementations, the trajectory simulation manager 211 may use a simulator, such as the ECLIPSE reservoir simulator or the INTERSECT reservoir simulator, to generate a predicted trajectory path (or a path section) and/or an estimated drill string. Additional examples of trajectory simulations are discussed in connection with FIGS. 3A-3B and FIG. 4.

In many implementations, the trajectory simulation manager 211 seeks to converge the divergent wellbore to a wellbore drilling plan before a target endpoint or a segment and/or the plan. In various implementations, a wellbore drilling plan is generated based on wellbore data 218, which may identify one or more aspects of a wellbore. In some instances, the wellbore drilling plan identifies an original trajectory path for drilling a wellbore throughout one or more (or all) measurement depths. The wellbore drilling plan may exhibit one or more bends, doglegs, and/or curves throughout the length of a planned wellbore. Deviations from a wellbore drilling plan may be indicated in the wellbore data 218, such as when a wellbore deviates and exhibits an unplanned amount of curvature and/or tortuosity.

In some embodiments, the wellbore data 218 includes information related to the earth, rock, ground, or formation through which the wellbore traverses. For example, the wellbore data 218 may include geological data, geophysical data, and/or lithology data for the formation(s). The wellbore data 218 may include details related to rock composition, structure, type, porosity, permeability, pressure, temperature, presence of hydrocarbons or other fluid, or any other property.

The subsurface structure system 202 further includes the T&D computation manager 212. In various implementations, the T&D computation manager 212 computes predictive torque and drag metrics using the predicted trajectory paths 220 generated by the trajectory simulation manager 211.

In one or more implementations, the torque and drag values include a predicted hook load, a predictive surface torque, a buckling limit, an axial force depth profile, and/or a side force depth profile. For example, a buckling limit may include a sinusoidal buckling limit or a helical buckling limit.

For context, a hook load includes the force experienced by the drilling rig due to the combined weight of the drill string (including drill pipes, collars, etc.), the drill bit, and the bottom hole assembly. A surface torque includes the force on the surface required to rotate the entire drill string and the bit. Sinusoidal buckling includes compressive forces that may deform the drilling pipes in the wellbore when the bit is pushed to the formation. Helical buckling includes a more extreme form of buckling and occurs when compressive forces pass through sinusoidal buckling and exceed the helical buckling limit. An axial force includes the force of the drill string, such as a weight-on-bit of a downhole tool, the weight of the drill string, a hook load applied by a drill rig, or another applicable axial force. A contact force includes the force between the drill string and the wellbore.

In various implementations, the T&D computation manager 212 performs a T&D analysis to determine T&D values 226. In many cases, the T&D computation manager 212 performs a T&D analysis by utilizing a finite element analysis (FEA) method. For example, an estimated drill string of a predicted trajectory path is represented, converted, and/or approximated by an FEA model to determine T&D values 226.

In various cases, finite element modeling includes a computational technique utilized to simulate and analyze the behavior of complex structures and systems. For example, based on the principles of discretization, a continuous object, such as the drill string, may be divided into a finite number of smaller, interconnected elements or segments. Each of these elements is defined by a set of mathematical equations, or shape functions, that describe its behavior under simulated, real-world conditions. The T&D computation manager 212 may leverage the FEA model to perform T&D analysis.

To elaborate, in various implementations, the T&D computation manager 212 implements an FEA model by generating a mesh of a drill string. In these cases, the T&D computation manager 212 divides the drill string into finite elements of simple geometric shapes such as lines, triangles, quadrilaterals, tetrahedra, hexahedra, or other shapes. The generated mesh may also include nodes connecting adjacent finite elements. The mesh of nodes and finite elements may typically be fine enough to capture the details, sections, tools, components, etc. of the drill string.

After the mesh is established, the T&D computation manager 212 implements defined mathematical formulations or shape functions to describe the behavior of each element, deriving functions based on physical principles and material properties of the drill string. For instance, the shape functions may be based on stress, strain, and deformation of or within the finite elements. In addition, the interaction and movement of the nodes may govern the shape functions, and therefore the shape functions of adjacent elements may be coupled based on commonly shared nodes.

In some instances, the shape functions may describe how the finite elements respond to various loads, boundary conditions, forces, torques, and other dynamics applied to or experienced by a drill string. Additionally, each element may be associated with properties, material characteristics, etc. of a portion of the drill string to collectively represent the entire drill string. From this data, the T&D computation manager 212 determines the T&D values 226 for the drill string.

In various implementations, the T&D computation manager 212 uses wellbore data 218 to determine T&D values 226 for a drill string. For example, the wellbore data 218 may indicate interaction data between a drill string and the formation to facilitate determining resultant contact forces and/or frictional forces between the drill string and the formation as described herein. In some embodiments, the wellbore data 218 identifies a coefficient of friction associated with various formations and/or subsurface features in relation to different downhole tools and/or drill strings that may come into contact with the formations, which is used by the T&D computation manager 212.

In some embodiments, the wellbore data 218 includes drill string data for a current drill string in a wellbore. For example, the drill string data includes information related to a BHA, bit, reamer, motor, RSS, stabilizer, collar, tool joint, or any other downhole tool or component connected to or implemented in a drill string. The drill string data may include information related to one or more lengths or sections of the drill string, such as one or more lengths of drill pipe, casing or liner, landing strings, running strings, inner strings, or any other portion or component of a drill string.

In various implementations, the drill string data identifies information about the drill string, such as the geometric configuration and material properties of the drill string and/or drilling tools. For example, the drill string data may identify the dimensions of individual drill string components such as the length and diameter of each component. The drill string data may also identify the weight, composition, and makeup of drill string components, as well as the specification of tool joints and other connection features. Additionally, the drill string data may identify drill string conditions during a downhole operation (e.g., real-time and/or simulated operation), such as weight-on-bit (WOB), rotary speed, drilling fluid properties, surface and/or downhole torque, hook load, or any other dynamics associated with the drill string.

The T&D computation manager 212 may receive the wellbore data 218, including drill string data, through one or more sensors, tools, measurement devices, client devices, or user input. The T&D computation manager 212 may receive wellbore data 218 and/or drill string data in real time and/or at regular intervals during an active downhole operation.

In some implementations, the T&D computation manager 212 may receive the wellbore data 218 and drill string data as part of planning or simulation for implementing a drill string (e.g., an estimated drill string) in a wellbore. In this way, the T&D computation manager 212 may receive and determine T&D values for an estimated drill string in a predicted trajectory path.

As shown, the subsurface structure system 202 further includes a T&D monitoring manager 213. In various implementations, the T&D monitoring manager 213 detects one or more risks related to the predicted torque and drag values within the predicted trajectory. For example, the T&D monitoring manager 213 detects one or more risks by comparing the predictive T&D values to known T&D limits.

To illustrate, in some instances, the T&D monitoring manager 213 compares a predicted hook load against the block weight and the maximum safe rig pull to determine whether the drill pipe can be run into the hole to the target depth or pulled out of the hole from the target depth. In another example, an axial force profile may be compared against the buckling limit and Von Mises limit to determine whether it exceeds the limit leading to excessive friction or drill string fractures. In yet another example, a side force profile may be compared against the side force limit to determine whether it exceeds the limit leading to excessive friction or casing fractures.

In one or more embodiments, when the T&D monitoring manager 213 detects one or more risks, the T&D monitoring manager 213 generates and provides risk reports 230. For instance, the T&D monitoring manager 213 generates and presents reports that include data from the predictive T&D analysis (e.g., a risk report includes one or more T&D values and/or comparisons). For example, the T&D monitoring manager 213 generates a report that includes information about calculated T&D metrics, various T&D limits, and a risk evaluation based on the calculated T&D metrics and the T&D limits. In some implementations, a risk report includes various tolerance levels relative to various risks.

As shown, the predictive lookahead system 206 includes the hydraulic pressure manager 214. In various implementations, the hydraulic pressure manager 214 uses wellbore data 218 to determine hydraulic pressure and/or pressure window values 228 for one or more segments along predicted trajectory paths 220. For example, the hydraulic pressure manager 214 uses mechanical Earth models, hydraulic engines, and/or hydraulic simulations to determine pressure window values 228 for a predicted trajectory path.

The hydraulic pressure manager 214 may also ensure that pressure window values 228 are within threshold risk limits, such as pressure window risk limits at various locations along a predicted trajectory path. If not, the hydraulic pressure manager 214 provides a risk report indicating that potential hydraulic fluid and/or formation failure is possible unless one or more drilling fluid parameters (e.g., mud weight) are modified. Indeed, based on the pressure window values 228, a risk report may indicate a pressure window influx risk based on the mud weight falling below a lower pressure window limit, which may cause formation pressure to overcome the hydrostatic pressure and result in an influx of formation fluids. Likewise, a risk report may indicate a pressure window loss risk based on the mud weight exceeding an upper pressure window limit, which may cause the hydraulic pressure to fracture that formation and result in fluid loss.

FIGS. 3A-3B illustrate examples of simulating a predicted trajectory path for a wellbore that has deviated from a wellbore drilling plan according to some implementations. In particular, FIG. 3A provides an example of a single predicted trajectory path, while FIG. 3B provides an example of multiple predicted trajectory paths. FIGS. 3A-3B show graphs of wellbore drilling plans based on depth and location. While a two-dimensional graph is shown, the same principles can be expanded to three-dimensional implementations.

As mentioned, FIG. 3A illustrates an example of simulating a projected trajectory path (or segment of a path). In particular, FIG. 3A shows a wellbore drilling plan 310 (e.g., an original wellbore drilling plan) that includes a first control point 312 and a target endpoint 320. In addition, the wellbore drilling plan 310 includes additional control points indicated by black solid circles (e.g., a second control point 314, a third control point 316, and a fourth control point 318). In various implementations, the wellbore drilling plan 310 represents a segment of a plan that ends at the target endpoint 320 (e.g., the solid square).

As shown, the predictive lookahead system 206 performs a check or survey to determine if the wellbore drilling plan 310 is being followed. For example, at the first control point 312 located at a first depth, the predictive lookahead system 206 identifies the current location of the drill (e.g., a drill bit or BHA), which is shown as survey point 322.

In various implementations, the predictive lookahead system 206 determines if the current drill location is beyond a threshold distance from a corresponding checkpoint (e.g., at the same depth or pipe stand). For example, the predictive lookahead system 206 determines if the survey point 322 is over a threshold distance from the first control point 312. If yes, then the predictive lookahead system 206 simulates a projected trajectory path to converge back to the wellbore drilling plan 310. As shown, the predictive lookahead system 206 generates a first predicted trajectory path 330 that converges with the wellbore drilling plan 310 at a first convergence point 340 before the target endpoint 320. In various implementations, the predictive lookahead system 206 generates a predicted trajectory path that converges at one of the control points.

In various implementations, the predictive lookahead system 206 generates the T&D values and/or hydraulic pressure for the first predicted trajectory path 330. For example, the predictive lookahead system 206 determines an estimated drill string that follows the first predicted trajectory path 330. Then, based on the current portion of the drill string and the estimated portion of the drill string, the predictive lookahead system 206 utilizes various T&D computations and/or hydraulic pressure computations described above to determine T&D values and/or hydraulic pressure values.

If the T&D values exceed a threshold torque and drag risk limit (e.g., one or more T&D limits corresponding to the operational capabilities of the drill string, drill bit, and/or rig), the predictive lookahead system 206 may provide a risk report that indicates a torque or drag risk associated with the first predicted trajectory path. Likewise, if the hydraulic pressure values exceed a threshold pressure window limit (e.g., one or more hydraulic pressure limits corresponding to the operational capabilities of the drill string, annulus, casing, and/or surrounding formations), the predictive lookahead system 206 may provide a risk report that indicates a pressure window risk associated with the first predicted trajectory path. Based on either or both of these risk reports, the predictive lookahead system 206 may determine whether to continue or pause drilling. For example, the predictive lookahead system 206 halts drilling until another predicted trajectory path is determined that does not exceed the threshold torque and drag risk limit and/or pressure window limits.

In various implementations, the predictive lookahead system 206 generates a predicted trajectory path that violates the maximum dogleg parameter of a steering assembly of a drill bit attached to a drill string. Stated differently, the predictive lookahead system 206 generates a predicted trajectory path that turns too sharply. In these implementations, the predictive lookahead system 206 may re-simulate a new predicted trajectory path that does not violate the maximum dogleg parameter. In various implementations, the maximum dogleg capability refers to the maximum deviation from a straight wellbore path section and accounts for both inclination (vertical deviation) and azimuth (horizontal deviation).

In some implementations, the predictive lookahead system 206 is unable to simulate a predicted trajectory path that reaches the wellbore drilling plan 310 before the target endpoint 320 (or a target depth) without violating the maximum dogleg parameter. In some implementations, the predictive lookahead system 206 converges with the wellbore drilling plan 310 as soon as possible without violating the maximum dogleg parameter and/or indicates the status of the predicted trajectory path to a client device.

FIG. 3B illustrates an example of simulating multiple projected trajectory paths. FIG. 3B expands upon FIG. 3A by adding a second predicted trajectory path 332 and a third predicted trajectory path 334. For example, upon determining to simulate a predicted trajectory path, the predictive lookahead system 206 generates multiple paths taking different routes back to the wellbore drilling plan 310. In some instances, multiple predicted trajectory paths overlap for a portion of the predicted path.

As mentioned, the first predicted trajectory path 330 starts at the survey point 322 and joins the wellbore drilling plan 310 at the first convergence point 340. The second predicted trajectory path 332 starts at the survey point 322 and joins the wellbore drilling plan 310 at a second convergence point 342 while the third predicted trajectory path 334 starts at the survey point 322 and joins the wellbore drilling plan 310 at the target endpoint 320. Indeed, each predicted trajectory path converges with the wellbore drilling plan 310 at or before the target endpoint 320 indicated in a wellbore drilling plan 310.

For each predicted trajectory path, the predictive lookahead system 206 can determine T&D values and/or hydraulic pressure values for an estimated drill string and/or drilling environment, as described above. When multiple predicted trajectory paths and estimated drill strings are calculated, the predictive lookahead system 206 may compare and/or rank the predicted trajectory paths based on their risk scores. For example, the predictive lookahead system 206 determines a risk score for each predicted trajectory path based on its T&D values and/or hydraulic pressure values. Then, the predictive lookahead system 206 ranks the predicted trajectory paths based on their risk scores. Furthermore, in some instances, the predictive lookahead system 206 selects the predicted trajectory path with the lowest risk score (e.g., the highest or most favorable ranked).

FIG. 4 illustrates an example of simulating multiple iterations of a predicted trajectory path according to some implementations. As shown, FIG. 4 includes components from FIG. 3A, such as the wellbore drilling plan 310 with the target endpoint 320 and the first predicted trajectory path 330 from the survey point 322 to the first convergence point 340.

In the context of FIG. 4, the predictive lookahead system 206 determines the first predicted trajectory path 330, determines T&D values and/or hydraulic pressure values for the first predicted trajectory path 330, and determines that proceeding along the path is within the risk threshold limits. However, the drill struggles to follow the first predicted trajectory path 330.

To illustrate, FIG. 4 includes a wellbore 416 that represents the actual path of the drill. As shown, the wellbore 416 deviates from the first predicted trajectory path 330 and is not on track to converge with the wellbore drilling plan 310 at the first convergence point 340. Accordingly, when the drill reaches another survey point depth, the predictive lookahead system 206 re-iterates the process of determining if the wellbore 416 has deviated from the first predicted trajectory path 330 and, if so, simulating an updated predicted trajectory path 426 (or multiple predicted trajectory paths).

As shown, based on taking a survey at a second survey depth of the updated current location of the drill, the predictive lookahead system 206 determines that a second survey point 424 is beyond a threshold distance from a control point 414 along the first predicted trajectory path 330. In some instances, the predictive lookahead system 206 compares the second survey point 424 to a corresponding control point along the wellbore drilling plan 310.

Based on determining that the second survey point 424 is beyond the threshold distance, the predictive lookahead system 206 generates the updated predicted trajectory path 426 to converge with the wellbore drilling plan 310 at an additional convergence point 440 (e.g., at or before the target endpoint 320 without violating maximum dogleg capabilities). For the updated predicted trajectory path 426, the predictive lookahead system 206 may ensure that the T&D values do not exceed the threshold torque and drag risk limits and/or the hydraulic pressure values do not exceed the threshold pressure window limits.

The predictive lookahead system 206 may repeat this process at various control points and/or depths. For example, each time the wellbore deviates from the wellbore drilling plan 310 or a current predicted trajectory path, the predictive lookahead system 206 generates and selects an updated predicted trajectory path to converge with the wellbore drilling plan 310 (or a segment) before the target endpoint 320.

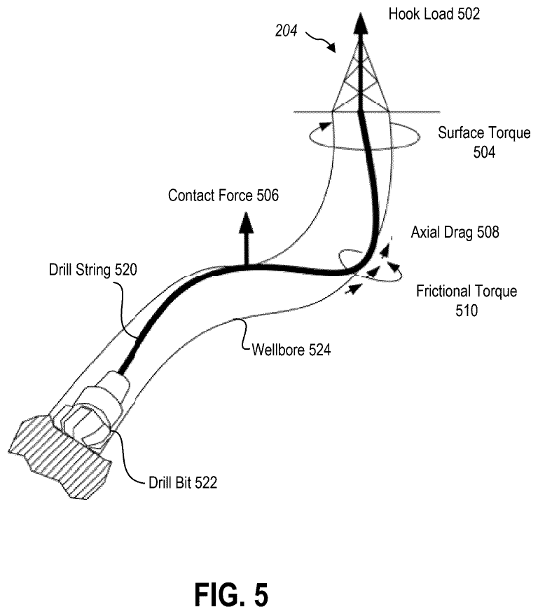

FIG. 5 illustrates various forces affecting the T&D values according to some implementations. As shown in FIG. 5, a downhole drilling system 204 experiences torque and drag effects based on a drill string 520 (and drill bit 522) that makes various contact with a wellbore 524. T&D is sometimes caused by the non-straight and non-smooth wellbore drilling paths. Various forces may impact equipment and/or a formation detrimentally. For instance, a contact force, axial drag, and/or frictional torque may cause unwanted wellbore wall breakage (e.g., a borehole wall) and/or unnecessary wear to a drill string.

FIG. 5 includes examples of various T&D metrics. As shown, FIG. 5 includes a hook load 502, surface torque 504, contact force 506, axial drag 508, and frictional torque 510. When simulating a predicted trajectory path, the predictive lookahead system 206 may determine T&D values for one or more of these metrics, as described above. Indeed, the predictive lookahead system 206 may determine the hook load 502, the surface torque 504, the contact force 506, the axial drag 508, and/or the frictional torque 510 for a predicted trajectory path.

In various implementations, determining T&D values includes the predictive lookahead system 206 computing T&D-related metrics using a stiff-string T&D model based on the simulated trajectory (e.g., predicted trajectory path) for at least a section of the path. In various implementations, the simulated T&D results include surface values and/or depth profiles. In one or more implementations, the predictive lookahead system 206 determines or computes a predicted hook load and/or a surface torque. In some instances, the predictive lookahead system 206 determines or computes buckling limits, including a sinusoidal buckling limit and a helical buckling limit. In one or more implementations, the predictive lookahead system 206 determines or computes an axial force (e.g., axial drag) depth profile. In some cases, the predictive lookahead system 206 determines or computes a side force (e.g., contact force) depth profile.

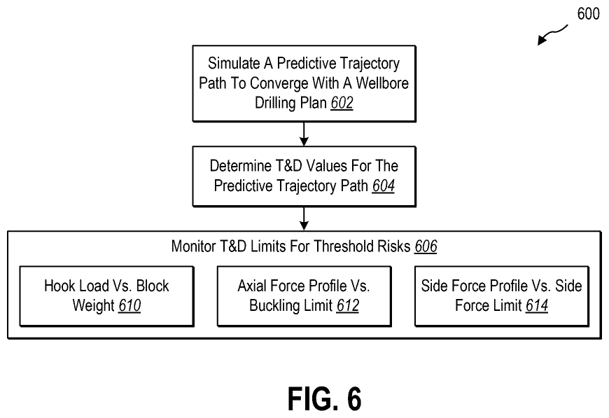

FIG. 6 illustrates monitoring T&D limits for a predicted trajectory path according to some implementations. FIG. 6 includes acts 600 for the predictive lookahead system 206 monitoring T&D limits. In particular, FIG. 6 corresponds to comparing simulated T&D values and metrics with the various T&D limits within a trajectory path (or path section). While FIG. 6 provides some examples of torque and drag risk limit monitoring, the predictive lookahead system 206 may also monitor and compare additional or different T&D values and metrics as part of monitoring T&D limits.

As shown, FIG. 6 includes act 602 of the predictive lookahead system 206 simulating a predicted trajectory path to converge with a wellbore drilling plan, as described above. FIG. 6 also includes act 604 of the predictive lookahead system 206 determining T&D values for the predicted trajectory path, as described above.

In addition, FIG. 6 includes act 606 of the predictive lookahead system 206 monitoring T&D limits for threshold risks. In particular, act 604 includes various actions for detecting when a threshold torque and drag risk limit has been exceeded. To illustrate, the act 604 includes a first action 610 of the predictive lookahead system 206 comparing a predicted hook load with the block weight and/or the maximum safe rig pull. For example, the predictive lookahead system 206 determines whether the drill pipe can be run into the hole to the target depth or pulled out of the hole from the target depth.

The act 604 includes a second action 612 of the predictive lookahead system 206 comparing the axial force profile with a buckling limit and/or Von Mises limit. For instance, if the predictive lookahead system 206 determines that the axial force profile exceeds a limit, implementing the predictive trajectory path may result in excessive friction or drill pipe fractures.

The act 606 includes a third action 614 of the predictive lookahead system 206 comparing the side force profile with a side force limit. For example, if the predictive lookahead system 206 determines that the side force profile exceeds the limit, implementing the predictive trajectory path may result in excessive friction or casing fractures.

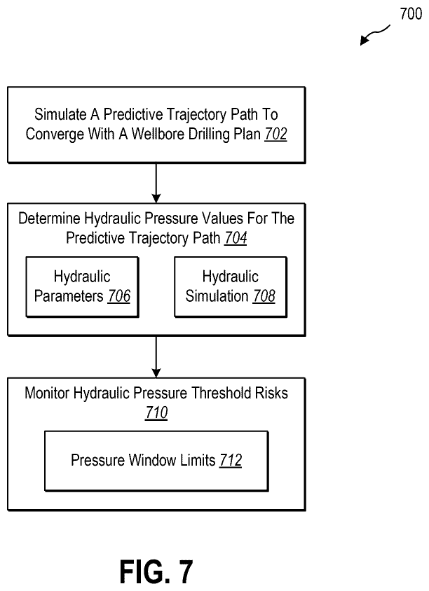

FIG. 7 illustrates the monitoring of pressure window limits for hydraulic pressure in a predicted trajectory path according to some implementations. FIG. 7 includes act 700 for the predictive lookahead system 206 to monitor pressure window limits corresponding to hydraulic pressure. In one or more implementations, the predictive lookahead system 206 uses lookahead hydraulics and geomechanics predictions to ensure that drilling operations along a predicted trajectory path stay within acceptable hydraulic pressure risk limits. By doing so, the predictive lookahead system 206 can detect and warn of future hydraulic pressure or formation failures along a predicted trajectory path when hydraulic parameters are determined to be outside of pressure windows unless the hydraulic parameters are modified.

In various implementations, FIG. 7 corresponds to comparing simulated hydraulic pressure values and metrics with the various hydraulic pressure limits within a trajectory path (or path section). While FIG. 7 provides some examples of window pressure limit monitoring, the predictive lookahead system 206 may also monitor and compare additional or different hydraulic pressure values and metrics as part of monitoring pressure window limits.

As shown, FIG. 7 includes act 702 of the predictive lookahead system 206 simulating a predicted trajectory path to converge with a wellbore drilling plan, as described above. For example, the predictive lookahead system 206 generates one or more predicted trajectory paths from a current position or location of the drill bit to return to the wellbore drilling plan by or at a target endpoint. In various implementations, a predicted trajectory path includes working out tolerances, building casing schedules, and/or determining fluid programs corresponding to hydraulic pressures.

FIG. 7 also includes act 704 of the predictive lookahead system 206 determining hydraulic pressure values for the predicted trajectory path. As shown, act 704 is associated with hydraulic parameters 706 and hydraulic simulation 708. In various implementations, the predictive lookahead system 206 obtains hydraulic parameters 706 corresponding to fluid properties, trajectories, temperatures, geometries, etc., that correspond to the predicted trajectory path. In some instances, the hydraulic parameters 706 are measured and/or updated based on the current location of the drill bit, BHA, and/or previous drilling path. In various implementations, hydraulic parameters include future parameters estimated as part of the predicted trajectory path.

As mentioned, the predictive lookahead system 206 may use hydraulic simulation 708 to determine hydraulic pressure values. For instance, in various implementations, the predictive lookahead system 206 runs a hydraulic simulation with the correct fluid properties, trajectories, temperatures, and geometries to determine hydraulic parameters. In various implementations, the hydraulic simulation corresponds to a computational fluid dynamics model with a hydraulic engine that determines one or more hydraulic pressures.

For additional context, hydraulic pressures include pore pressure, breakdown pressure, breakout pressure, and fracture pressure. In various implementations, each hydraulic pressure may be compared to its own hydraulic pressure window, formation pressure window, and/or mud weight window (these terms are sometimes used interchangeably).

Act 710 includes monitoring hydraulic parameters threshold risks. For example, the predictive lookahead system 206 determines the one or more determined hydraulic pressures to one or more pressure windows (e.g., pressure window limits 712) to ensure the drill will operate within acceptable hydraulic pressure risk limits.

In some implementations, the predictive lookahead system 206 uses a geomechanics model to derive a pressure window. For example, a one-dimensional mechanical Earth model is used with the wellbore data and/or predicted trajectory path to determine formation stresses. Then, one or more pressure windows are determined from the formation stresses. In various implementations, the predictive lookahead system 206 otherwise obtains pressure windows for safe hydraulic pressure operating limits.

The predictive lookahead system 206 can compare the hydraulic pressure to the pressure window to determine whether drilling within the predicted trajectory path is safe. In particular, the predictive lookahead system 206 determines whether formation pressures along the predicted trajectory path will exceed limits and, if so, reports the need to change hydraulic parameters to prevent future failures.

The pressure window can have a low limit and a high limit. The low pressure window limit indicates when the hydraulic pressure is too low, which can cause an influx (also called a kick). To elaborate, a kick refers to an unexpected influx of formation fluids (such as oil, gas, or water) into the wellbore during the drilling process due to the hydraulic pressure falling below the lower pressure window threshold. In some instances, low hydraulic pressure occurs if the wellbore pressure (mud weight) is insufficient to counteract the formation pressure. Kicks can lead to loss of well control, well blowouts, equipment damage, and even catastrophic incidents. Indeed, lower hydrostatic pressure due to mud loss can cause wellbore instability.

The high pressure window limit indicates when the hydraulic pressure is too high, which can cause fractures or losses. For example, if the mud weight exceeds the upper limit of the window, the hydraulic pressure can cause fractures in the formation, leading to fluid losses and causing fracture gradient and lost circulation. Fracture gradient occurs when hydraulic pressure is larger than formation pressure, which causes formation breaks (e.g., rock breaks) and allows drilling fluid (such as drilling mud) to flow into fractures or fissures. In various implementations, if the mud weight (density) exceeds the fracture pressure, this can lead to induced fractures and mud losses. Lost circulation occurs when drilling mud escapes into subsurface formations during drilling. Lost circulation can cause reduced annular velocity and affect mud carrying capacity.

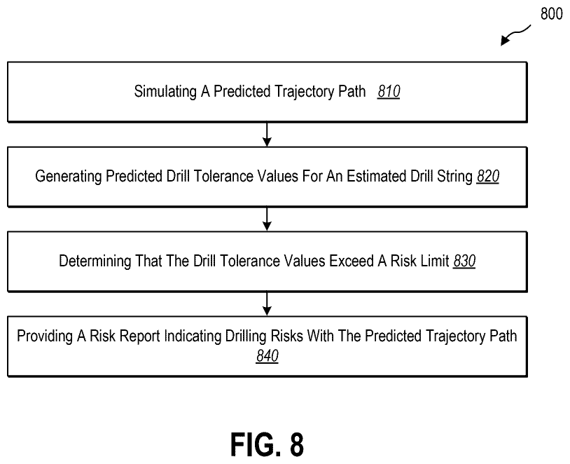

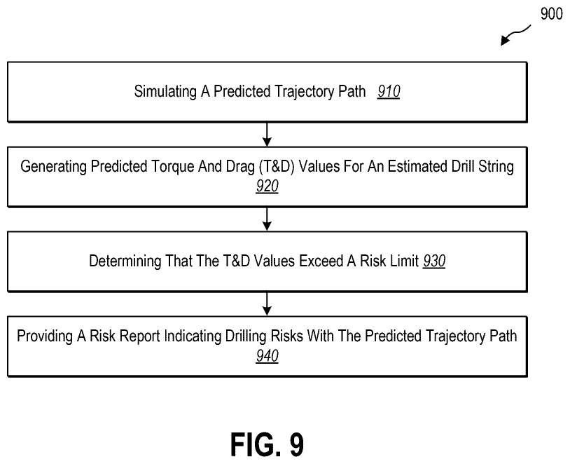

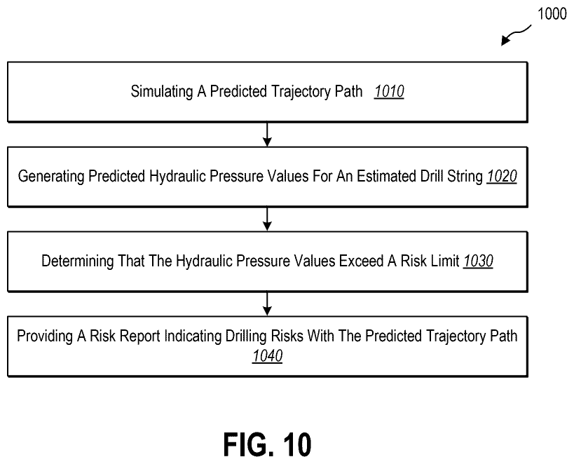

Now turning to FIGS. 8-10, which illustrate example flowcharts that include various series of acts for using the predictive lookahead system according to some implementations. In particular, FIG. 9 illustrates an example series of acts representing a computer-implemented method for predicting one or more drilling tolerance values for one or more predicted trajectories in a drilling environment, FIG. 9 illustrates an example series of acts representing a computer-implemented method for predicting one or more torque and drag values for one or more predicted trajectories in a drilling environment, and FIG. 10 illustrates an example series of acts representing a computer-implemented method for predicting one or more hydraulic pressure values for one or more predicted trajectories in a drilling environment.

While FIGS. 8-10 each illustrate a series of acts according to one or more implementations, alternative implementations may omit, add to, reorder, and/or modify any of the acts shown. Furthermore, the acts of FIGS. 8-10 may each be performed as part of a method (e.g., a computer-implemented method). Alternatively, a computer-readable medium may include instructions that, when executed by a processing system with a processor, cause a computing device to perform the acts of FIGS. 8-10.

In some implementations, a system (e.g., a processing system comprising a processor) may perform the acts of FIGS. 8-10. For example, the acts include a system that includes a processing system and computer memory including instructions that, when executed by the processing system, cause the system to perform various actions or steps.

FIG. 8, in particular, shows a series of acts 800 including an act 810 of simulating a predicted trajectory path. For instance, in example implementations, act 810 involves simulating a first predicted trajectory path from a current wellbore location within a wellbore to at or before a target endpoint indicated in a wellbore drilling plan.

As shown, the series of acts 800 includes act 820 of generating predicted drill tolerance values for an estimated drill string. For instance, in example implementations, act 820 involves generating predicted drilling tolerance values for an estimated drill string within the first predicted trajectory path.

As shown, the series of acts 800 includes act 830 of determining that the drill tolerance values exceed a risk limit. For instance, in example implementations, act 830 involves determining that the predicted drilling tolerance values for the estimated drill string within the first predicted trajectory path exceed a threshold drilling risk limit.

As shown, the series of acts 800 includes act 840 of providing a risk report indicating drilling risks with the predicted trajectory path. For instance, in example implementations, act 840 involves providing a risk report that indicates a drilling tolerance risk associated with the first predicted trajectory path.

In various implementations, as part of the series of acts 800, the predicted drilling tolerance values include torque and drag values, the threshold drilling risk limit includes a threshold torque and drag risk limit, and/or the risk report includes a torque or drag risk associated with the first predicted trajectory path.

In some implementations, as part of the series of acts 800, the predicted drilling tolerance values include hydraulic pressure values, the threshold drilling risk limit includes a threshold pressure window risk limit, and/or the risk report includes a pressure window risk associated with the first predicted trajectory path.

FIG. 9, shows a series of acts 900 includes an act 910 of simulating a predicted trajectory path. For instance, in example implementations, act 910 involves simulating a first predicted trajectory path from a current wellbore location within a wellbore to at or before a target endpoint indicated in a wellbore drilling plan.

As shown, the series of acts 900 includes an act 920 of generating predicted torque and drag (T&D) values for an estimated drill string. For instance, in example implementations, act 920 involves generating predicted torque and drag values for an estimated drill string within the first predicted trajectory path.

As shown, the series of acts 900 includes act 930 of determining that the T&D values exceed a torque and drag risk limit. For instance, in example implementations, act 930 involves determining that the predicted torque and drag values for the estimated drill string within the first predicted trajectory path exceed a threshold torque and drag risk limit.

As shown, the series of acts 900 includes act 940 of providing a risk report indicating drilling risk with the predicted trajectory path. For instance, in example implementations, act 940 involves providing a risk report in response that indicates a torque or drag risk associated with the first predicted trajectory path

In some implementations, the series of acts 900 includes determining the current wellbore location within the wellbore; comparing the current wellbore location to a control point along the wellbore drilling plan; determining that the current wellbore location exceeds a drilling plan distance deviation threshold; and simulating the first predicted trajectory path based on the drilling plan distance deviation threshold being exceeded. In some implementations, the current wellbore location is measured from a bottom hole assembly (BHA) near a drill bit attached to a drilling end of a drill string within the wellbore. In some implementations, simulating the first predicted trajectory path includes generating the estimated drill string that resides within the first predicted trajectory path. In some implementations, simulating the first predicted trajectory path to converge with the wellbore drilling plan at or before the target endpoint includes ensuring that a maximum dogleg parameter of a steering assembly of a drill bit attached to a drill string is not violated.

In some implementations, the target endpoint includes a section endpoint of the wellbore drilling plan. In some implementations, determining the predicted torque and drag values includes using a torque and drag model to calculate a predicted hook load, a predictive surface torque, a buckling limit, an axial force depth profile, or a side force depth profile on the estimated drill string. In some implementations, determining that the predicted torque and drag values for the estimated drill string within the first predicted trajectory path exceed the threshold torque and drag risk limit includes comparing the predicted torque and drag values to a known torque limit or a known drag limit.

In some implementations, determining that the predicted torque and drag values for the estimated drill string within the first predicted trajectory path exceed the threshold torque and drag risk limit further includes determining that the predicted hook load, the predictive surface torque, the buckling limit, the axial force depth profile, or the side force depth profile will cause the estimated drill string within the first predicted trajectory path to exceed the threshold torque and drag risk limit. In some implementations, determining that torque or drag forces exceed the threshold torque and drag risk limit includes detecting that the estimated drill string will become stuck, jammed, or restricted at one or more locations along the first predicted trajectory path.

In some implementations, determining that torque or drag forces exceed the threshold torque and drag risk limit includes detecting that a drill pipe in the estimated drill string will fracture within the first predicted trajectory path based on comparing the axial force depth profile with the buckling limit. In some implementations, determining that torque or drag forces exceed the threshold torque and drag risk limit includes detecting that an estimated casing will fracture within the first predicted trajectory path based on comparing the side force depth profile with a side force limit. In some implementations, the buckling limit includes a sinusoidal buckling limit or a helical buckling limit.

In some implementations, the series of acts 900 includes receiving real-time drilling data of a drill string in the wellbore and calibrating the torque and drag model based on the real-time drilling data. In some implementations, the series of acts 900 includes simulating a second predicted trajectory path from the current wellbore location that converges with the wellbore drilling plan at or before the target endpoint at a different location than the first predicted trajectory path. In some implementations, the series of acts 900 includes ranking the first predicted trajectory path and the second predicted trajectory path based on the predicted torque and drag values determined for each predicted trajectory path.

In some implementations, the techniques described herein relate to a computer-implemented method for predicting torque and drag for one or more predicted trajectories in a drilling environment, including: simulating a first predicted trajectory path from a current wellbore location within a wellbore to at or before a target endpoint indicated in a wellbore drilling plan; generating predicted torque and drag values, including a predicted hook load, a predicted surface torque, a buckling limit, an axial force, or a contact force for an estimated drill string within the first predicted trajectory path; and determining that the predicted torque and drag values for the estimated drill string within the first predicted trajectory path exceed a threshold torque and drag risk limit.

In some implementations, the series of acts 900 includes determining an updated current wellbore location upon implementing the first predicted trajectory path, determining that the updated current wellbore location exceeds a drilling plan distance deviation threshold from a control point of the first predicted trajectory path, and simulating a second predicted trajectory path from the updated current wellbore location to converge with the wellbore drilling plan at a new convergence point. In some implementations, the first predicted trajectory path is simulated based on a reservoir simulator.

FIG. 10 shows a series of acts 1000 that includes an act 1010 of simulating a predicted trajectory path. For instance, in example implementations, act 1010 involves simulating a first predicted trajectory path from a current wellbore location within a wellbore to at or before a target endpoint indicated in a wellbore drilling plan.

As shown, the series of acts 1000 includes act 1020 of generating predicted hydraulic pressure values for an estimated drill string. For instance, in example implementations, act 1020 involves generating predicted hydraulic pressure values for an estimated drill string within the first predicted trajectory path.

As shown, the series of acts 1000 includes act 1030 of determining that the hydraulic pressure values exceed a risk limit. For instance, in example implementations, act 1030 involves determining that the predicted hydraulic pressure values for the estimated drill string within the first predicted trajectory path exceed a threshold pressure window risk limit.

As shown, the series of acts 1000 includes act 1040 of providing a risk report indicating drilling risks with the predicted trajectory path. For instance, in example implementations, act 1040 involves providing a risk report, in response, that indicates a pressure window risk associated with the first predicted trajectory path.

FIG. 11 illustrates certain components that may be included within a computer system 1100. The computer system 1100 may be used to implement various computing devices, components, and systems described herein (e.g., by performing computer-implemented instructions). As used herein, a “computing device” refers to electronic components that perform a set of operations based on a set of programmed instructions. Computing devices include groups of electronic components, client devices, server devices, etc.

In various implementations, the computer system 1100 represents one or more of the client devices, server devices, or other computing devices described above. For example, the computer system 1100 may refer to various types of network devices capable of accessing data on a network, a cloud computing system, or another system. For instance, a client device may refer to a mobile device such as a mobile telephone, a smartphone, a personal digital assistant (PDA), a tablet, a laptop, or a wearable computing device (e.g., a headset or smartwatch). A client device may also refer to a non-mobile device such as a desktop computer, a server node (e.g., from another cloud computing system), or another non-portable device.

The computer system 1100 includes a processing system including a processor 1101. The processor 1101 may be a general-purpose single- or multi-chip microprocessor (e.g., an Advanced Reduced Instruction Set Computer (RISC) Machine (ARM)), a special-purpose microprocessor (e.g., a digital signal processor (DSP)), a microcontroller, a programmable gate array, etc. The processor 1101 may be referred to as a central processing unit (CPU) and may cause computer-implemented instructions to be performed. Although the processor 1101 shown is just a single processor in the computer system 1100 of FIG. 11, in an alternative configuration, a combination of processors (e.g., an ARM and DSP) could be used.

The computer system 1100 also includes memory 1103 in electronic communication with the processor 1101. The memory 1103 may be any electronic component capable of storing electronic information. For example, the memory 1103 may be embodied as random-access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM), registers, and so forth, including combinations thereof.

The instructions 1105 and the data 1107 may be stored in the memory 1103. The instructions 1105 may be executable by the processor 1101 to implement some or all of the functionality disclosed herein. Executing the instructions 1105 may involve the use of the data 1107 stored in the memory 1103. Any of the various examples of modules and components described herein may be implemented, partially or wholly, as instructions 1105 stored in memory 1103 and executed by the processor 1101. Any of the various examples of data described herein may be among the data 1107 stored in memory 1103 and used during the execution of the instructions 1105 by the processor 1101.

A computer system 1100 may also include one or more communication interface(s) 1109 for communicating with other electronic devices. The one or more communication interface(s) 1109 may be based on wired communication technology, wireless communication technology, or both. Some examples of the one or more communication interface(s) 1109 include a Universal Serial Bus (USB), an Ethernet adapter, a wireless adapter that operates according to an Institute of Electrical and Electronics Engineers (IEEE) 1102.11 wireless communication protocol, a Bluetooth® wireless communication adapter, and an infrared (IR) communication port.

A computer system 1100 may also include one or more input device(s) 1111 and one or more output device(s) 1113. Some examples of the one or more input device(s) 1111 include a keyboard, mouse, microphone, remote control device, button, joystick, trackball, touchpad, and light pen. Some examples of the one or more output device(s) 1113 include a speaker and a printer. A specific type of output device typically included in a computer system 1100 is a display device 1115. The display device 1115 used with implementations disclosed herein may use any suitable image projection technology, such as liquid crystal display (LCD), light-emitting diode (LED), gas plasma, electroluminescence, or the like. A display controller 1117 may also be provided, for converting data 1107 stored in the memory 1103 into text, graphics, and/or moving images (as appropriate) shown on the display device 1115.

The various components of the computer system 1100 may be coupled together by one or more buses, including a power bus, a control signal bus, a status signal bus, and a data bus, among others. For clarity, the various buses are illustrated in FIG. 11 as a bus system 1119.

This disclosure describes a subjective data application system within the framework of a network. In this document, a “network” refers to one or more data links that enable electronic data transport between computer systems, modules, and other electronic devices. A network may include public networks such as the Internet as well as private networks. When information is transferred or provided over a network or another communication connection (either hardwired, wireless, or both), the computer correctly views the connection as a transmission medium. Transmission media may include a network and/or data links that carry the required program code in the form of computer-executable instructions or data structures, which may be accessed by a general-purpose or special-purpose computer.

In addition, the network described herein may represent a network or a combination of networks (such as the Internet, a corporate intranet, a virtual private network (VPN), a local area network (LAN), a wireless local area network (WLAN), a cellular network, a wide area network (WAN), a metropolitan area network (MAN), or a combination of two or more such networks) over which one or more computing devices may access the various systems described in this disclosure. Indeed, the networks described herein may include one or multiple networks that use one or more communication platforms or technologies for transmitting data. For example, a network may include the Internet or another data link that enables transporting electronic data between respective client devices and components (e.g., server devices and/or virtual machines thereon) of the cloud computing system.

Furthermore, upon reaching various computer system components, program code means in the form of computer-executable instructions or data structures may be transferred automatically from transmission media to non-transitory computer-readable storage media (devices), or vice versa. For example, computer-executable instructions or data structures received over a network or data link may be buffered in random-access memory (RAM) within a network interface module (NIC) and then eventually transferred to computer system RAM and/or less volatile computer storage media (devices) in a computer system. Thus, it should be understood that computer-readable storage media (devices) may be included in computer system components that also (or even primarily) use transmission media.

Computer-executable instructions include instructions and data that, when executed by a processor, cause a general-purpose computer, special-purpose computer, or special-purpose processing device to perform a certain function or group of functions. In some implementations, computer-executable and/or computer-implemented instructions are executed by a general-purpose computer to turn the general-purpose computer into a special-purpose computer implementing elements of the disclosure. The computer-executable instructions may include, for example, binaries, intermediate format instructions such as assembly language, or even source code. Although the subject matter has been described in language specific to structural features and/or methodological acts, the subject matter defined in the appended claims is not necessarily limited to the features or acts described above. Rather, the described features and acts are disclosed as example forms of implementing the claims.

Those skilled in the art will appreciate that the disclosure may be practiced in network computing environments with many types of computer system configurations, including personal computers, desktop computers, laptop computers, message processors, handheld devices, multiprocessor systems, microprocessor-based or programmable consumer electronics, network PCs, minicomputers, mainframe computers, mobile telephones, PDAs, tablets, pagers, routers, switches, and the like. The disclosure may also be practiced in distributed system environments where local and remote computer systems, which are linked (either by hardwired data links, wireless data links, or a combination of hardwired and wireless data links) through a network, both perform tasks. In a distributed system environment, program modules may be located in both local and remote memory storage devices.

The techniques described herein may be implemented in hardware, software, firmware, or any combination thereof unless specifically described as being implemented in a specific manner. Any features described as modules, components, or the like may also be implemented together in an integrated logic device or separately as discrete but interoperable logic devices. If implemented in software, the techniques may be realized, at least in part, by a non-transitory processor-readable storage medium, including instructions that, when executed by at least one processor, perform one or more of the methods described herein (including computer-implemented methods). The instructions may be organized into routines, programs, objects, components, data structures, etc., which may perform particular tasks and/or implement particular data types, and which may be combined or distributed as desired in various implementations.

Computer-readable media may be any available media that may be accessed by a general-purpose or special-purpose computer system. Computer-readable media that store computer-executable instructions are non-transitory computer-readable storage media (devices). Computer-readable media that carry computer-executable instructions are transmission media. Thus, by way of example, implementations of the disclosure may include at least two distinctly different kinds of computer-readable media such as non-transitory computer-readable storage media (devices) and transmission media.

As used herein, computer-readable storage media (devices) may include RAM, ROM, EEPROM, CD-ROM, solid-state drives (SSDs) (e.g., based on RAM), Flash memory, phase-change memory (PCM), other types of memory, other optical disk storage, magnetic disk storage, or other magnetic storage devices, or any other medium that can be used to store desired program code means in the form of computer-executable instructions or data structures and that can be accessed by a general-purpose or special-purpose computer.

The steps and/or actions of the methods described herein may be interchanged with one another without departing from the scope of the claims. In other words, unless a specific order of steps or actions is required for the proper operation of the method being described, the order and/or use of specific steps and/or actions may be modified without departing from the scope of the claims.

The term “determining” encompasses a wide variety of actions, and therefore, “determining” may include calculating, computing, processing, deriving, investigating, looking up (e.g., looking up in a table, a data repository, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The terms “comprising,” “including,” and “having” are intended to be inclusive and mean that there may be additional elements other than the listed elements. Additionally, it should be understood that references to “one implementation” or “implementations” of the present disclosure are not intended to be interpreted as excluding the existence of additional implementations that also incorporate the recited features. For example, any element or feature described concerning an implementation herein may be combinable with any element or feature of any other implementation described herein, where compatible.

The present disclosure may be embodied in other specific forms without departing from its spirit or characteristics. The described implementations are to be considered illustrative and not restrictive. The scope of the disclosure is indicated by the appended claims rather than by the foregoing description. Changes that come within the meaning and range of equivalency of the claims are to be embraced within their scope.

What is claimed is:

1. A computer-implemented method for predicting one or more drilling tolerance values for one or more predicted trajectories in a drilling environment, comprising:
simulating a first predicted trajectory path from a current wellbore location within a wellbore to at or before a target endpoint indicated in a wellbore drilling plan;
generating predicted drilling tolerance values for an estimated drill string within the first predicted trajectory path;
determining that the predicted drilling tolerance values for the estimated drill string within the first predicted trajectory path exceed a threshold drilling risk limit; and
providing a risk report in response that indicates a drilling tolerance risk associated with the first predicted trajectory path.

2. The computer-implemented method of claim 1, wherein:
the predicted drilling tolerance values include torque and drag values;
the threshold drilling risk limit includes a threshold torque and drag risk limit; and
the risk report includes a torque or drag risk associated with the first predicted trajectory path.

3. The computer-implemented method of claim 2, wherein:
the predicted drilling tolerance values include hydraulic pressure values;
the threshold drilling risk limit includes a threshold pressure window risk limit; and
the risk report includes a pressure window risk associated with the first predicted trajectory path.

4. A computer-implemented method for predicting one or more torque and drag values for one or more predicted trajectories in a drilling environment, comprising:
simulating a first predicted trajectory path from a current wellbore location within a wellbore to at or before a target endpoint indicated in a wellbore drilling plan;
generating predicted torque and drag values for an estimated drill string within the first predicted trajectory path;
determining that the predicted torque and drag values for the estimated drill string within the first predicted trajectory path exceed a threshold torque and drag risk limit; and
providing a risk report in response that indicates a torque or drag risk associated with the first predicted trajectory path.

5. The computer-implemented method of claim 4, further comprising:
determining the current wellbore location within the wellbore;
comparing the current wellbore location to a control point along the wellbore drilling plan;
determining that the current wellbore location exceeds a drilling plan distance deviation threshold; and
simulating the first predicted trajectory path based on the drilling plan distance deviation threshold being exceeded.

6. The computer-implemented method of claim 5, wherein the current wellbore location is measured from a bottom hole assembly (BHA) near a drill bit attached to a drilling end of a drill string within the wellbore.

7. The computer-implemented method of claim 4, wherein simulating the first predicted trajectory path includes generating the estimated drill string that resides within the first predicted trajectory path.

8. The computer-implemented method of claim 4, wherein:
simulating the first predicted trajectory path to converge with the wellbore drilling plan at or before the target endpoint includes ensuring that a maximum dogleg parameter of a steering assembly of a drill bit attached to a drill string is not violated; and
the first predicted trajectory path is simulated based on a reservoir simulator.

9. The computer-implemented method of claim 4, wherein the target endpoint includes a section endpoint of the wellbore drilling plan.

10. The computer-implemented method of claim 4, wherein determining the predicted torque and drag values includes using a torque and drag model to calculate a predicted hook load, a predictive surface torque, a buckling limit, an axial force depth profile, or a side force depth profile on the estimated drill string.

11. The computer-implemented method of claim 10, wherein determining that the predicted torque and drag values for the estimated drill string within the first predicted trajectory path exceed the threshold torque and drag risk limit includes comparing the predicted torque and drag values to a known torque limit or a known drag limit.

12. The computer-implemented method of claim 11, wherein determining that the predicted torque and drag values for the estimated drill string within the first predicted trajectory path exceed the threshold torque and drag risk limit further includes determining that the predicted hook load, the predictive surface torque, the buckling limit, the axial force depth profile, or the side force depth profile will cause the estimated drill string within the first predicted trajectory path to exceed the threshold torque and drag risk limit.

13. The computer-implemented method of claim 12, wherein determining that torque or drag forces exceed the threshold torque and drag risk limit includes detecting that the estimated drill string will become restricted at one or more locations along the first predicted trajectory path.

14. The computer-implemented method of claim 12, wherein determining that torque or drag forces exceed the threshold torque and drag risk limit includes detecting that a drill pipe in the estimated drill string will fracture within the first predicted trajectory path based on comparing the axial force depth profile with the buckling limit.

15. The computer-implemented method of claim 12, wherein determining that torque or drag forces exceed the threshold torque and drag risk limit includes detecting that an estimated casing will fracture within the first predicted trajectory path based on comparing the side force depth profile with a side force limit.

16. The computer-implemented method of claim 10, wherein the buckling limit includes a sinusoidal buckling limit or a helical buckling limit.

17. The computer-implemented method of claim 10, further comprising:
receiving real-time drilling data of a drill string in the wellbore; and
calibrating the torque and drag model based on the real-time drilling data.

18. The computer-implemented method of claim 4, further comprising:
simulating a second predicted trajectory path from the current wellbore location that converges with the wellbore drilling plan at or before the target endpoint at a different location than the first predicted trajectory path; and
ranking the first predicted trajectory path and the second predicted trajectory path based on the predicted torque and drag values determined for each predicted trajectory path.

19. The computer-implemented method of claim 4, further comprising:
determining an updated current wellbore location upon implementing the first predicted trajectory path;
determining that the updated current wellbore location exceeds a drilling plan distance deviation threshold from a control point of the first predicted trajectory path; and
simulating a second predicted trajectory path from the updated current wellbore location to converge with the wellbore drilling plan at a new convergence point.

20. A computer-implemented method for predicting one or more hydraulic pressure values for one or more predicted trajectories in a drilling environment, comprising:
simulating a first predicted trajectory path from a current wellbore location within a wellbore to at or before a target endpoint indicated in a wellbore drilling plan;
generating predicted hydraulic pressure values for an estimated drill string within the first predicted trajectory path;
determining that the predicted hydraulic pressure values for the estimated drill string within the first predicted trajectory path exceed a threshold pressure window risk limit; and
providing a risk report in response that indicates a pressure window risk associated with the first predicted trajectory path.
